(19) United States
(12) Patent Application Publication
(10) Pub. No.: US 2026/0344262 A1
(43) Pub. Date: Oct. 29, 2026

(54) LIGHT EMITTING DISPLAY APPARATUS

(71) Applicant: LG Display Co., Ltd., Seoul (KR)

(72) Inventors: TaeHan PARK, Paju-si (KR); Seungyeop LEE, Paju-si (KR); Seongku LEE, Paju-si (KR)

(73) Assignee: LG Display Co., Ltd., Seoul (KR)

(21) Appl. No.: 19/429,934

(22) Filed: Dec. 22, 2025

(30) Foreign Application Priority Data
Dec. 30, 2024 (KR) 10-2024-0201454

(51) Int. Cl. H10K 59/80; H10K 59/38

(52) U.S. Cl. CPC H10K 59/878; H10K 59/38

(57) ABSTRACT

A light emitting display apparatus can include a substrate having a plurality of subpixels having an emission area and a non-emission area, a pixel circuit disposed in the non-emission area on the substrate, at least one insulating layer disposed on the pixel circuit, and a color filter disposed on the insulating layer and corresponding to at least one of the plurality of subpixels. One or more of the plurality of subpixels can include a low-reflection optical portion having at least one transverse electric (TE) mode reflection pattern adjacent to or in contact with the color filter in the emission area.

### CROSS-REFERENCE TO RELATED APPLICATIONS

This application claims priority to Korean Patent Application No. 10-2024-0201454, filed in Republic of Korea on Dec. 30, 2024, the entirety of which is hereby expressly incorporated by reference for all purposes.

### BACKGROUND

### Technical Field

The present disclosure relates to a light emitting display apparatus.

### Description of the Related Art

With the advancement of the information age, a demand for a display apparatus for displaying an image has increased in various forms. Therefore, various types of display apparatuses such as a liquid crystal display (LCD) apparatus, an organic light emitting display (OLED) apparatus, a micro light emitting diode (LED) display apparatus and a quantum dot display (QD) apparatus have been recently used.

Among the display apparatuses, the organic light emitting display apparatus is a self-luminance type. In the organic light emitting display apparatus, hole and electron are injected into an emission layer from an anode electrode for hole injection and a cathode electrode for electron injection, and the injected hole and electron are bonded to each other. Herein, as the bonded hole and electron exciton fall from the excited state to the ground state, the organic light emitting display apparatus can emit light and display an image.

Such organic light emitting display apparatus has primarily employed a polarizer on a display surface of a panel to reduce external light reflection. However, when the organic light emitting display apparatus uses a polarizer, transmittance can decrease, thereby reducing panel efficiency and increasing power consumption.

### SUMMARY OF THE DISCLOSURE

One or more embodiments of the present disclosure can provide a light emitting display apparatus capable of reducing reflectance, improving light efficiency, and enhancing reflected color and visual perception without using a polarizer.

Additional advantages and features of the disclosure will be set forth in part in the description which follows and in part will become apparent to those having ordinary skill in the art upon examination of the following or can be learned from practice of the disclosure. The objectives and other advantages of the disclosure can be realized and attained by the structure particularly pointed out in the written description and claims hereof as well as the appended drawings.

A light emitting display apparatus according to one or more embodiments of the present disclosure can include a substrate including a plurality of subpixels having an emission area and a non-emission area, a pixel circuit disposed in the non-emission area on the substrate, at least one insulating layer disposed on the pixel circuit, and a color filter disposed on the at least one insulating layer, the color filter corresponding to at least one of the plurality of subpixels, one or more of the plurality of subpixels can include a low-reflection optical portion having at least one transverse electric (TE) mode reflection pattern adjacent to or in contact with the color filter in the emission area.

According to one or more embodiments of the present disclosure, a light emitting display apparatus capable of reducing reflectance, improving light efficiency, and enhancing reflected color and visual perception without using a polarizer can be provided.

The light emitting display apparatus according to one or more embodiments of the present disclosure can reduce reflectance without using a polarizer, improve light efficiency, and enhance reflected color and viewing quality, and thus can reduce power consumption to enable low-power driving and reduce production energy to achieve an ESG (Environmental, Social, Governance) effect.

The effects of the present disclosure are not limited to the aforesaid, but other effects not described herein will be clearly understood by those skilled in the art from the following descriptions.

The details of the present disclosure described in technical problem, technical solution, and advantageous effects do not specify essential features of claims, and thus, the scope of claims is not limited by the details described in detailed description of the invention.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure, and together with the description serve to explain the principles and examples of the disclosure.

FIG. 1 illustrates a light emitting display apparatus according to one or more embodiment of the present disclosure.

FIG. 2 is a circuit diagram illustrating a subpixel of a light emitting display apparatus according to an embodiment of the present disclosure.

FIG. 3 illustrates a plurality of subpixels in a display panel according to one embodiment of the present disclosure.

FIG. 4 is a cross-sectional view taken along line I-I′ of FIG. 3 according to one embodiment of the present disclosure.

FIG. 5 illustrates a change in a path of external light in a display panel according to one embodiment of the present disclosure.

FIG. 6 illustrates a change in a path of emitted light in a display panel according to one embodiment of the present disclosure.

FIG. 7 is a cross-sectional view taken along line I-I′ of FIG. 3 according to another embodiment of the present disclosure.

FIG. 8 illustrates a plurality of subpixels in a display panel according to another embodiment of the present disclosure.

FIG. 9 is a cross-sectional view taken along line II-II′ of FIG. 8 according to another embodiment of the present disclosure.

FIG. 10 is a cross-sectional view taken along line II-II′ of FIG. 8 according to another embodiment of the present disclosure.

FIG. 11 illustrates a plurality of subpixels in a display panel according to another embodiment of the present disclosure.

FIG. 12 is a cross-sectional view taken along line III-III′ of FIG. 11 according to another embodiment of the present disclosure.

FIG. 13 is a cross-sectional view taken along line III-III′ of FIG. 11 according to another embodiment of the present disclosure.

FIG. 14 illustrates a plurality of subpixels in a display panel according to another embodiment of the present disclosure.

FIG. 15 is a cross-sectional view taken along line IV-IV′ of FIG. 14 according to another embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction of thereof can be exaggerated for clarity, illustration, and/or convenience.

### DETAILED DESCRIPTION OF THE EMBODIMENTS

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure can be thorough and complete, to assist those skilled in the art to understand the inventive concepts without limiting the protected scope of the present disclosure.

Shapes (e.g., sizes, lengths, widths, heights, thicknesses, locations, radii, diameters, and areas), sizes, ratios, angles, numbers, and the like disclosed herein, including those illustrated in the drawings are merely examples, and thus, the present disclosure is not limited to the illustrated details. Any implementation described herein as an “example” is not necessarily to be construed as preferred or advantageous over other implementations. It is, however, noted that the relative dimensions of the components illustrated in the drawings are part of the present disclosure.

When the term such as “comprise,” “have,” “include,” “contain,” “constitute,” “made of,” “formed of,” or the like is used with respect to one or more elements, one or more other elements can be added unless a term such as “only” or the like is used. The terms used in the present disclosure are merely used in order to describe example embodiments, and are not intended to limit the scope of the present disclosure. The terms of a singular form can include plural forms unless the context clearly indicates otherwise.

In construing an element, the element is construed as including an error region although there is no explicit description thereof.

In describing a positional relationship, for example, when the positional order is described as “on,” “above,” “below,” "beneath", and “next,” the case of no contact therebetween can be included, unless “just” or “direct” is used.

If it is mentioned that a first element is positioned “on” a second element, it does not mean that the first element is essentially positioned above the second element in the figure. The upper part and the lower part of an object concerned can be changed depending on the orientation of the object. Consequently, the case in which a first element is positioned “on” a second element includes the case in which the first element is positioned “below” the second element as well as the case in which the first element is positioned “above” the second element in the figure or in an actual configuration.

In describing a temporal relationship, for example, when the temporal order is described as using terms such as “after,” “subsequent,” “next,” and “before,” a case which is not continuous can be included, unless “just” or “direct” is used.

It will be understood that, although the terms such as “first,” “second,” etc. can be used herein to describe various elements, these elements should not be limited by these terms. These terms are only used to distinguish one element from another. For example, a first element could be termed a second element, and, similarly, a second element could be termed a first element.

In describing elements of the present disclosure, the terms such as “first,” “second,” “A,” “B,” “(a),” “(b),” or the like can be used. These terms are intended to identify the corresponding element(s) from the other element(s), and these are not used to define the essence, basis, order, or number of the elements.

For the expression that an element is “connected,” “coupled,” “attached,” “adhered,” or the like to another element, the element may not only be directly connected, coupled, attached, adhered, or the like to another element, but also be indirectly connected, coupled, attached, adhered, or the like to another element with one or more intervening elements disposed or interposed between the elements, unless otherwise specified.

For the expression that an element is “contacts,” “overlaps,” or the like with another element, the element may not only directly contact, overlap, or the like with another element, but also indirectly contact, overlap, or the like with another element with one or more intervening elements disposed or interposed between the elements, unless otherwise specified.

The term such as “at least one” should be understood as including any and all combinations of one or more of the associated listed items. For example, “at least one among a first element, a second element and a third element” can include all combinations of two or more elements selected from the first, second and third elements as well as each element of the first, second and third elements.

Features of various embodiments of the present disclosure can be partially or entirety coupled to or combined with each other, can be technically associated with each other, and can be variously inter-operated, linked or driven together. The embodiments of the present disclosure can be implemented or carried out independently of each other, or can be implemented or carried out together in a co-dependent or related relationship. In one or more aspects, the components of each apparatus according to various embodiments of the present disclosure are operatively coupled and configured. Further, the term “can” fully encompasses all the meanings and coverage of the term “may” and vice versa.

In the following description, various example embodiments of the present disclosure are described in detail with reference to the accompanying drawings. All the components of each display apparatus/device according to all embodiments of the present disclosure are operatively coupled and configured. With respect to reference numerals to elements of each of the drawings, the same elements can be illustrated in other drawings, and like reference numerals can refer to like elements unless stated otherwise. The same or similar elements can be denoted by the same reference numerals even though they are depicted in different drawings. In addition, for convenience of description, a scale, dimension, size, and thickness of each of the elements illustrated in the accompanying drawings can be different from an actual scale, dimension, size, and thickness, and thus, embodiments of the present disclosure are not limited to a scale, dimension, size, and thickness illustrated in the drawings.

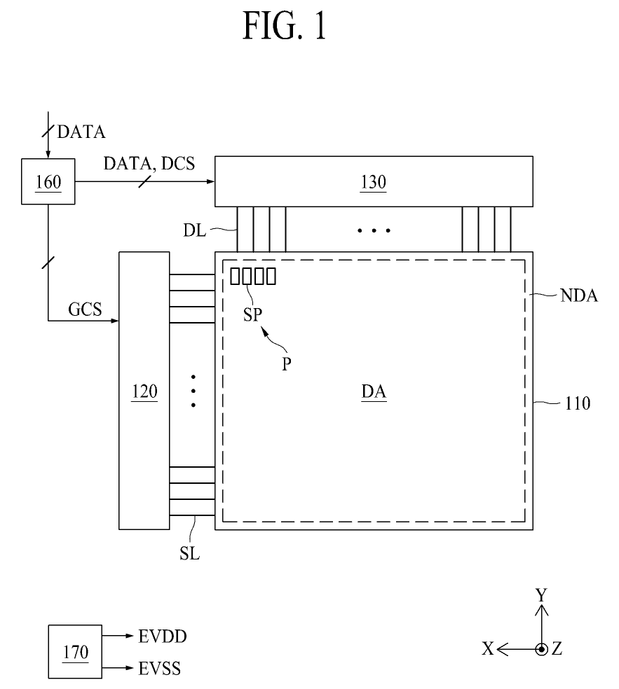

FIG. 1 illustrates a light emitting display apparatus according to one or more embodiments of the present disclosure.

Hereinafter, an X-axis represents a direction parallel to a scan line, a Y-axis represents a direction parallel to a data line, and a Z-axis represents a height direction of the light emitting display apparatus.

A light emitting display apparatus according to an embodiment of the present disclosure is implemented as an organic light emitting display apparatus, but can also be implemented as a liquid crystal display apparatus, a quantum dot lighting emitting diode display apparatus, or an electrophoretic display apparatus.

Referring to FIG. 1, the light emitting display apparatus according to an embodiment of the present disclosure can include a display panel 110, a scan driver 120 (or a gate driver) embedded in the display panel 110, a data driver 130 connected to the display panel 110, a timing controller 160 controlling the scan driver 120 and the data driver 130, and a power circuit 170.

The display panel 110 includes a display area DA and a non-display area NDA surrounding the display area DA. The non-display area NDA can surround the display area DA entirely or only in part(s). The display panel 110 includes pixels P provided in the display area DA to display an image. Each of the pixels P can include a plurality of subpixels SP. The structure of the subpixel SP can be variously changed according to the type of the light emitting display apparatus. For example, the subpixels SP can be formed in a top emission type, a bottom emission type, or a dual emission type according to the structure. The subpixels SP indicate a unit capable of forming a color filter of a specific type or capable of emitting a color of itself without forming a color filter. The subpixels SP can have one or more other light-emitting areas according to light-emitting characteristics. For example, the plurality of subpixels SP can be arranged in a stripe type or a quad type, but embodiments of the present disclosure are not limited thereto. The color type, arrangement type, arrangement order, and the like of the subpixels SP can be configured in various forms according to the light-emitting characteristics, lifespan of the apparatus, spec of the apparatus, and the like.

The display panel 110 can include data lines DL and scan lines SL (or gate lines) connected to the subpixels SP. The data lines DL can be arranged to cross the scan lines SL. Each of the subpixels SP of the display panel 110 can be connected to any one of the data lines DL and any one of the scan lines SL. The data lines DL can supply a data voltage supplied from the data driver 130 to each of the subpixels SP. The scan lines SL can supply a scan signal supplied from the scan driver 120 to each of the subpixels SP

Each of the subpixels SP is turned-on by the scan signal. When the data voltage of the data line DL is supplied to a gate electrode of a driving transistor, a light emitting element can emit light according to a drain-to-source current of the driving transistor. The scan driver 120 can receive a scan control signal GCS from the timing controller 160. The scan driver 120 can supply the scan signals or emission control signal to the scan lines SL by using the scan control signal GCS.

The scan driver 120 can be configured in a gate driver in panel GIP manner in the non-display area NDA outside one side or both sides of the display area DA. Alternatively, the scan driver 120 can be manufactured as a driving chip, mounted on a flexible film, and attached to the non-display area NDA outside one side or both sides of the display area DA in a tape automated bonding TAB manner.

The data driver 130 can receive digital video data DATA and a data control signal DCS from the timing controller 160. The data driver 130 converts the digital video data DATA into analog positive/negative data voltages by using the data control signal DCS and supplies the analog positive/negative data voltages to the data lines DL.

The timing controller 160 receives digital video data DATA and timing signals from a host system. The timing signals can include a vertical synchronization signal, a horizontal synchronization signal, a data enable signal, a dot clock, and the like. The vertical synchronization signal is a signal defining one frame period. The horizontal synchronization signal is a signal defining one horizontal period required for supplying the data voltages to the pixels of one horizontal line of the display panel 110. The data enable signal defines a period in which valid data is input. The dot clock is a signal repeated at a predetermined short period.

The timing controller 160 can generate the data control signal DCS for controlling an operation timing of the data driver 130 and the scan control signal GCS for controlling an operation timing of the scan driver 120 based on the timing signals. The timing controller 160 can output the scan control signal GCS to the scan driver 120 to control the scan driver 120 and output the digital video data DATA and data control signal DCS to the data driver 130 to control the data driver 130.

The power circuit 170 can generate and supply a plurality of driving voltages required for an operation of all circuit configurations of the light emitting display apparatus by using an input voltage. The power circuit 170 can generate a first power source voltage EVDD (or pixel power voltage), a second power supply voltage EVSS (or common power voltage) and an initialization voltage Vref (or reference voltage) and supply the generated voltages to the display panel 110. The power circuit 170 can generate and supply various driving voltages required for operations of the scan driver 120, the data driver 130, and the timing controller 160.

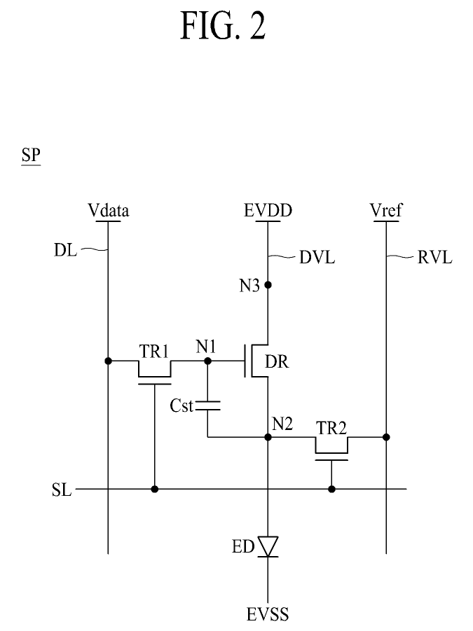

FIG. 2 is a circuit diagram illustrating a subpixel of a light emitting display apparatus according to an embodiment of the present disclosure. Each subpixel SP of FIG. 1 or other figures can have the subpixel configuration of FIG. 2 or other types of subpixel configurations.

Referring to FIG. 2, each of pixels P includes the plurality of subpixels SP constituting a unit pixel. In each of the plurality of subpixels SP, there are a pixel circuit having 3T(Transistor)1C(Capacitor) including the driving transistor DR, the first switching transistor TR1, the second switching transistor TR2 and the storage capacitor Cst, and the light emitting device ED, but not limited thereto. Each subpixel SP can further include a compensation circuit. In this case, the subpixel SP can have various structures such as 3T2C, 4T1C, 4T2C, 5T1C, 5T2C, 6T1C, 6T2C, 7T1C, and 7T2C.

At least one thin film transistor DR, TR1 and TR2 of each subpixel SP can include a gate electrode, a source electrode, and a drain electrode. Since the source electrode and the drain electrode can be changed according to a voltage and a current direction applied to the gate electrode without being fixed, any one of the source electrode and the drain electrode can be represented as a first electrode, and the other can be represented as a second electrode. The at least one transistor DR, TR1, and TR2 can use at least one of polysilicon semiconductor, amorphous silicon semiconductor, and oxide semiconductor. The transistors DR, TR1, and TR2 can be P-type or N-type, or P-type and N-type can be interchangeably used.

The driving transistor DR corresponds to a transistor for driving the light emitting device ED, and the driving transistor DR includes the first node N1 to which the data voltage Vdata is applied, the second node N2 connected to a pixel electrode (first electrode or anode electrode) of the light emitting device ED, and the third node N3 connected to the first power voltage line DVL (or pixel power voltage line) and supplied with the first power voltage EVDD (or pixel power voltage). For example, the driving transistor DR can generate a data current from the first power voltage EVDD supplied from the first power voltage line DVL and can supply the data current to the first electrode of the light emitting device ED.

The first switching transistor TR1 can serve to supply the data voltage Vdata supplied from the data line DL to the first node N1 of the driving transistor DR. The second switching transistor TR2 can serve to supply the reference voltage Vref supplied from the reference line RVL to the second node N2 of the driving transistor DR or can output a voltage of the second node N2 of the driving transistor DR. The storage capacitor Cst can be connected between the first node N1 and the second node N2 of the driving transistor DR. The storage capacitor Cst can serve to maintain the data voltage Vdata supplied to the driving transistor DR for one frame, but embodiments of the present disclosure are not limited thereto.

The light emitting device ED can include the pixel electrode (first electrode or anode electrode) connected to the second node N2 of the driving transistor DR, and a second power voltage (EVSS) (or a common power voltage) can be applied to a common electrode (a second electrode or a cathode electrode). The light emitting device ED can emit light in response to a driving current generated by the driving transistor DR through an emission layer (or organic emission layer) between the first electrode and the second electrode. The pixel electrode of the light emitting device ED can be an independent electrode for each light emitting device, and the common electrode and the emission layer of the light-emitting device ED can be a common layer shared by the entire light emitting devices, but embodiments of the present disclosure are not limited thereto.

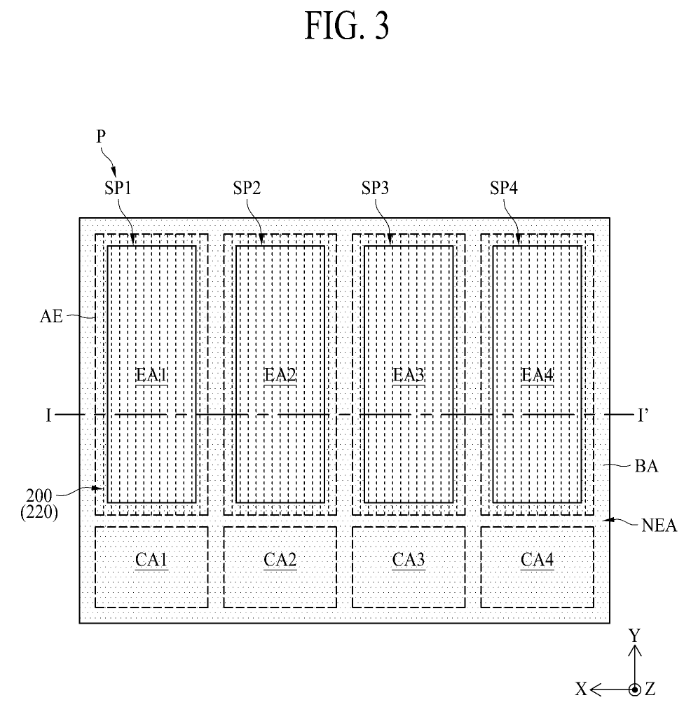

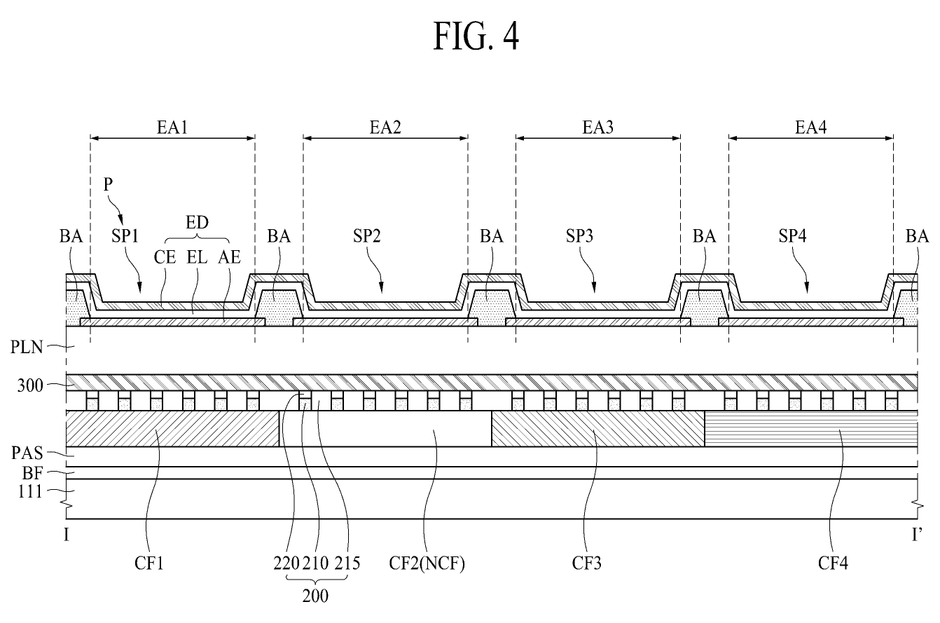

FIG. 3 illustrates a plurality of subpixel in a display panel according to one embodiment of the present disclosure. FIG. 4 is a cross-sectional view taken along line I-I′ of FIG. 3 according to one embodiment of the present disclosure.

Referring to FIGS. 3 and 4, the display panel 110 according to one embodiment of the present disclosure can be configured to a top emission type, a bottom emission type, or a dual emission type. For example, the display panel 110 can be implemented in the bottom emission type, but the embodiments of the present disclosure are not limited thereto.

The display panel 110 according to one embodiment of the present disclosure can include a plurality of subpixels SP1, SP2, SP3 and SP4. Each of the subpixels SP1, SP2, SP3 and SP4 can include an emission area EA1, EA2, EA3 and EA4 and a non-emission area NEA. The non-emission area NEA of each of the subpixels SP1, SP2, SP3 and SP4 can include a pixel circuit CA1, CA2, CA3 and CA4. For example, each of the subpixels SP1, SP2, SP3 and SP4 can be provided with at least one scan line SL extending in a first direction (or an X-axis direction), a plurality of data lines DL extending in a second direction (or a Y-axis direction), and one or more power voltage lines DVL and RVL, but the embodiments of the present disclosure are not limited thereto.

The plurality of subpixels SP1, SP2, SP3 and SP4 can be unit pixels that different colors. The plurality of subpixels SP1, SP2, SP3 and SP4 can be arranged in a stripe type in a first direction (or X-axis direction) or a second direction (or Y-axis direction). For example, the plurality of subpixels SP1, SP2, SP3 and SP4 can be arranged in the first direction (or X-axis direction), but not limited thereto. The arrangement order or type of the plurality of subpixels can be variously changed.

The plurality of subpixels SP1, SP2, SP3 and SP4 can include the emission area EA1, EA2, EA3 and EA4, in which a light emitting element ED configured with a pixel electrode AE, an emission layer EL, and a common electrode CE is disposed to emit light, and the non-emission area NEA. For example, the pixel circuit CA1, CA2, CA3 and CA4 of each of the subpixels SP1, SP2, SP3 and SP4 can be disposed in the non-emission area NEA. For example, the pixel circuit CA1, CA2, CA3 and CA4 of each of the subpixels SP1, SP2, SP3 and SP4 can include at least one thin film transistor DR, TR1 and TR2 and a storage capacitor Cst, but the embodiments of the present disclosure are not limited thereto.

The display panel 110 according to one embodiment of the present disclosure can be implemented in a bottom emission type, and pixel circuits CA1, CA2, CA3 and CA4 disposed in the emission areas EA1, EA2, EA3 and EA4 and the non-emission area NEA of each of the subpixels SP1, SP2, SP3 and SP4 may not overlap with each other or can be at least partially overlapped with each other. For example, the emission areas EA1, EA2, EA3 and EA4 can be disposed at an upper side in a second direction (or a Y-axis direction), and the pixel circuits CA1, CA2, CA3 and CA4 in the non-emission area NEA can be disposed at a lower side in the second direction, but the embodiments of the present disclosure are not limited thereto.

The non-emission area NEA can further include a bank portion BA that covers an edge of the pixel electrode AE of each of the subpixels SP1, SP2, SP3 and SP4. The bank portion BA can be configured to cover the non-emission area NEA of each of the subpixels SP1, SP2, SP3 and SP4. For example, the bank portion BA can be configured to define the emission areas EA1, EA2, EA3 and EA4 of each of the subpixels SP1, SP2, SP3 and SP4. The bank portion BA can be disposed to surround a periphery of the emission areas EA1, EA2, EA3 and EA4 of each of the subpixels SP1, SP2, SP3 and SP4. The bank portion BA can be disposed between the pixel electrode AE and the emission layer EL of each of the subpixels SP1, SP2, SP3 and SP4.

The emission areas EA1, EA2, EA3 and EA4 can correspond to areas in which light is emitted in each of the subpixels SP1, SP2, SP3 and SP4. For example, each of the subpixels SP1, SP2, SP3 and SP4 can include the light emitting element ED configured by overlapping the pixel electrode AE, the emission layer EL, and the common electrode CE, and the emission areas EA1, EA2, EA3 and EA4 can correspond to the light emitting element ED of each of the subpixels SP1, SP2, SP3 and SP4.

The emission areas EA1, EA2, EA3 and EA4 can include first to fourth emission areas EA1, EA2, EA3 and EA4 that emit light of different colors from each other. For example, the emission areas EA1, EA2, EA3 and EA4 can overlap with corresponding color filters CF1, CF2, CF3 and CF4, and thus can emit light of different colors.

Each of the color filters CF1, CF2, CF3 and CF4 can emit light of different colors. For example, each of the color filters CF1, CF2, CF3 and CF4 can be composed of an organic material that transmits light of different colors. Each of the color filters CF1, CF2, CF3 and CF4 can include a first color filter CF1 that transmits red light, a second color filter CF2 that transmits white light, a third color filter CF3 that transmits blue light, and a fourth color filter CF4 that transmits green light.

The first emission area EA1 of the first subpixel SP1 can emit red light through the first color filter CF1, the second emission area EA2 of the second subpixel SP2 can emit white light without a color filter being disposed or through the second color filter CF2, the third emission area EA3 of the third subpixel SP3 can emit blue light through the third color filter CF3, and the fourth emission area EA4 of the fourth subpixel SP4 can emit green light through the fourth color filter CF4, but the embodiments of the present disclosure are not limited thereto.

Referring to FIG. 4, the display panel 110 according to one embodiment of the present disclosure can include a substrate 111, at least one insulating layer BF and PAS, the plurality of color filters CF1, CF2, CF3 and CF4, a low-reflection optical portion 200 and 300, a planarization layer PLN, the pixel electrode AE, the emission layer EL, the common electrode CE, and the bank portion BA. The low-reflection optical portion 200 and 300 according to one embodiment of the present disclosure can be configured to be adjacent to or in contact with the color filters CF1, CF2, CF3 and CF4 in each of the emission areas EA1, EA2, EA3 and EA4. For example, the low-reflection optical portion 200 and 300 can be disposed on each of the color filters CF1, CF2, CF3 and CF4.

At least one voltage signal line can be disposed on the substrate 111. For example, a plurality of data lines DL, a first power voltage line DVL, and a reference voltage line RVL can be disposed on the substrate 111. For example, the plurality of data lines DL, the first power voltage line DVL, and the reference voltage line RVL can be configured of the same material in the same layer as a light blocking layer disposed in the pixel circuits CA1, CA2, CA3 and CA4, but the embodiments of the present disclosure are not limited thereto.

The at least one insulating layer BF and PAS can be disposed on the substrate 111. The at least one insulating layer BF and PAS can be disposed on the pixel circuits CA1, CA2, CA3 and CA4, and the at least one insulating layer BF and PAS can include a buffer layer BF and a passivation layer PAS. For example, the buffer layer BF can be disposed on the substrate 111. The buffer layer BF can be configured to cover the at least one voltage signal line DL, DVL and RVL and the light blocking layer on the substrate 111. The pixel circuits CA1, CA2, CA3 and CA4 and the passivation layer PAS can be disposed on the buffer layer BF. For example, each of the pixel circuits CA1, CA2, CA3 and CA4 can include at least one thin film transistor DR, ST1 and ST2 and a storage capacitor Cst.

The at least one thin film transistor DR, ST1 and ST2 disposed between the buffer layer BF and the passivation layer PAS can further include a gate insulating layer and an interlayer insulating layer interposed between or covering an active layer, a gate electrode, and source/drain electrodes of the at least one thin film transistor DR, ST1 and ST2, but the embodiments of the present disclosure are not limited thereto. For example, the at least one insulating layer BF and PAS can be configured as a single layer or a multilayer including an inorganic insulating material such as silicon oxide (SiO_{X}), silicon nitride (SiN_{X}), or aluminum oxide (Al₂O₃), but the embodiments of the present disclosure are not limited thereto.

The plurality of color filters CF1, CF2, CF3 and CF4 can be disposed on the at least one insulating layer BF and PAS. For example, the plurality of color filters CF1, CF2, CF3 and CF4 can be disposed on the passivation layer PAS. The plurality of color filters CF1, CF2, CF3 and CF4 can be disposed to correspond to each of the subpixels SP1, SP2, SP3 and SP4. For example, a first color filter CF1 that converts white light emitted from the light emitting element ED into red light can be disposed in the first emission area EA1 of the first subpixel SP1. A second color filter CF2 that either is not disposed or emits white light emitted from the light emitting element ED as is can be disposed in the second emission area EA2 of the second subpixel SP2. A third color filter CF3 that converts white light emitted from the light emitting element ED into blue light can be disposed in the third emission area EA3 of the third subpixel SP3. A fourth color filter CF4 that converts white light emitted from the light emitting element ED into green light can be disposed in the fourth emission area EA4 of the fourth subpixel SP4.

The planarization layer PLN (or an overcoat layer) can be disposed on the passivation layer PAS and the plurality of color filters CF1, CF2, CF3 and CF4. The planarization layer PLN can be configured to planarize a step caused by the pixel circuits CA1, CA2, CA3 and CA4, the at least one voltage signal line DL, DVL and RVL, and the plurality of color filters CF1, CF2, CF3 and CF4 disposed on the substrate 111, and can be composed of an organic insulating material. For example, the planarization layer PLN can be composed of an organic material such as acryl resin, epoxy resin, phenolic resin, polyamide resin, or polyimide resin, but the embodiments of the present disclosure are not limited thereto.

The pixel electrode AE (a first electrode or an anode electrode), the emission layer EL (or an organic emission layer), and the common electrode CE (a second electrode or a cathode electrode) that constitute the light emitting element ED can be disposed on the planarization layer PLN. Further, the bank portion BA configured to define an aperture region (or the emission area) of the pixel electrode AE can further be disposed on the planarization layer PLN.

The pixel electrode AE can be disposed on the planarization layer PLN. The pixel electrode AE can be patterned and disposed for each of the subpixels SP1, SP2, SP3 and SP4 on the planarization layer PLN.

The pixel electrode AE can be formed of a transparent metal material or a semi-transmissive metal material. For example, the pixel electrode AE can be formed of a transparent conductive material TCO such as indium tin oxide ITO or indium zinc oxide IZO that can transmit light. The pixel electrode AE can be formed of a semi-transmissive conductive material such as magnesium Mg, silver Ag, or an alloy of magnesium Mg and silver Ag. For example, the pixel electrode AE formed of the semi-transmissive metal material can improve light extraction efficiency by a micro cavity. The pixel electrode AE can be an anode electrode of the light emitting device ED.

The bank portion BA can be disposed on the pixel electrode AE and the planarization layer OC. The bank portion BA can be disposed on the planarization layer OC to cover a portion of the edge of the pixel electrode AE. The bank portion BA can be configured to define an opening area (or emission area) of the pixel electrode AE. For example, the bank portion BA can be disposed between the pixel electrode AE and the emission layer EL. The opening area of the pixel electrode AE can correspond to the emission areas EA1, EA2, EA3 and EA4 of each subpixels SP1, SP2, SP3 and SP4. For example, the pixel electrode AE exposed by the bank portion BA can be electrically connected by being in direct contact with the emission layer EL and the common electrode CE, thereby forming the light emitting device ED. For example, the bank portion BA can be omitted.

The emission layer EL (or organic emission layer) can be disposed on the pixel electrode AE and the bank portion BA. The emission layer EL can include a hole transporting layer, an emission material layer, and an electron transporting layer. For example, when a voltage is applied to the pixel electrode AE and the common electrode CE, holes and electrons can move to the emission layer EL through the hole transporting layer and the electron transporting layer, respectively, and can be combined with each other in the emission layer EL to emit light. The emission layer EL can be a common layer commonly formed over the plurality of subpixels SP1, SP2, SP3 and SP4. For example, the emission layer EL can be a white emission layer that emits white light.

The emission layer EL according to one embodiment of the present disclosure can include two or more emission layers to emit white light. For example, the emission layer EL can be configured in a tandem structure including a first emission layer and a second emission layer vertically stacked to emit white light by mixing a first light and a second light. For example, the emission layer EL can also be configured by vertically stacking three or four emission layers, but the embodiments of the present disclosure are not limited thereto.

The common electrode CE can be disposed on the emission layer EL. The common electrode CE can be a common layer commonly formed over the plurality of subpixels SP1, SP2, SP3 and SP4. The common electrode CE can be disposed on the pixel electrode AE and the emission layer EL, which are in contact with each other, to constitute the light emitting device ED. For example, the common electrode CE can be formed of a metal material having high reflectance, such as a stacked structure (Ti/Al/Ti) of aluminum and titanium, a stacked structure (ITO/Al/ITO) of aluminum and ITO, Ag alloy, a stacked structure (ITO/Ag alloy/ITO) of Ag alloy and ITO, MoTi alloy, and a stacked structure (ITO/MoTi alloy/ITO) of MoTi alloy and ITO. The Ag alloy can be an alloy of silver (Ag), palladium (Pd), copper (Cu) and the like. The MoTi alloy can be an alloy of molybdenum (Mo) and titanium (Ti). The common electrode CE can be a cathode electrode of the light emitting device ED.

The display panel 110 according to one embodiment of the present disclosure can include the low-reflection optical portion 200 and 300 that is adjacent to or in contact with the color filters CF1, CF2, CF3 and CF4 in the emission areas EA1, EA2, EA3 and EA4 of each of the subpixels SP1, SP2, SP3 and SP4.

The low-reflection optical portion 200 and 300 according to one embodiment of the present disclosure can include a TE (Transverse Electric) mode reflection pattern 220.

The TE mode reflection pattern 220 can be configured as a plurality of TE mode reflection patterns 220, and the plurality of TE mode reflection patterns 220 can extend in a first direction (or an X-axis direction) or a second direction (or a Y-axis direction) of the emission areas EA1, EA2, EA3 and EA4, and can be arranged to be spaced apart from each other. For example, the plurality of TE mode reflection patterns 220 can extend in the second direction and can be arranged to be spaced apart from each other in the first direction.

The plurality of TE mode reflection patterns 220 can be configured such that a width of each TE mode reflection pattern 220 or a distance between adjacent TE mode reflection patterns 220 is smaller than a wavelength range of light of corresponding subpixels SP1, SP2, SP3 and SP4. For example, the plurality of TE mode reflection patterns 220 disposed in each of the subpixels SP1, SP2, SP3 and SP4 can be configured such that the widths or the distances are different from each other. For example, the width or the distance of the plurality of TE mode reflection patterns 220 can be 200 nm to 1000 nm, but the embodiments of the present disclosure are not limited thereto.

The TE mode reflection pattern 220 can include a conductive material or a conductive organic material. For example, an induced current can be generated through the conductive material in the TE mode reflection pattern 220. For example, the conductive material can include a metal material such as gold (Au), silver (Ag), aluminum (Al), copper (Cu), molybdenum-titanium (MoTi), indium tin oxide (ITO), indium zinc oxide (IZO), or indium gallium zinc oxide (IGZO). Further, the conductive organic material can include a conductive polymer material such as PEDOT:PSS, but the embodiments of the present disclosure are not limited thereto.

The TE mode reflection pattern 220 can generate an induced current to absorb or reflect TE mode light that is perpendicular to the pattern and can transmit TM mode light that is horizontal. For example, the TE mode refers to a case in which an electric field component of an electromagnetic wave is perpendicular to a propagation direction, and the TM (Transverse Magnetic) mode refers to a case in which the electric field component is parallel to the propagation direction. For example, when light propagates horizontally, a light component in which the electric field vibrates in a vertical direction (e.g., up and down) is the TE mode, and a light component in which the electric field vibrates in a horizontal direction (e.g., left and right) is the TM mode.

Referring to FIG. 4, the low-reflection optical portion 200 and 300 according to one embodiment of the present disclosure can be disposed on the color filters CF1, CF2, CF3 and CF4 of each of the subpixels SP1, SP2, SP3 and SP4. The low-reflection optical portion 200 and 300 can be disposed in each of the plurality of subpixels SP1, SP2, SP3 and SP4.

The low-reflection optical portion 200 and 300 can include a first low-reflection optical layer 200 and a second low-reflection optical layer 300. The first low-reflection optical layer 200 can be disposed on the color filters CF1, CF2, CF3 and CF4, and the second low-reflection optical layer 300 can be disposed on the first low-reflection optical layer 200.

The first low-reflection optical layer 200 can include a TE mode reflection pattern 220. For example, the first low-reflection optical layer 200 can include a light absorption pattern 210, the TE mode reflection pattern 220, and a protective layer 215.

The light absorption pattern 210 can be configured to have a light absorption characteristic. For example, the light absorption pattern 210 can include a light absorbing material or a black material. For example, the light absorption pattern 210 can include an insulating light absorbing material such as a black resin or graphite, but the embodiments of the present disclosure are not limited thereto. The light absorption pattern 210 can correspond to each of the TE mode reflection patterns 220. The light absorption pattern 210 can be disposed on the color filters CF1, CF2, CF3 and CF4. The TE mode reflection pattern 220 can be disposed on the light absorption pattern 210. The light absorption pattern 210 and the TE mode reflection pattern 220 can be configured in the same pattern as each other.

The protective layer 215 can be configured to support the light absorption pattern 210 and the TE mode reflection pattern 220. The protective layer 215 can be composed of a non-conductive material. For example, the protective layer 215 can be composed of an organic film or an inorganic film having non-conductivity. The protective layer 215 can be configured to surround a periphery of the stacked light absorption pattern 210 and the TE mode reflection pattern 220.

The second low-reflection optical layer 300 can be disposed on the first low-reflection optical layer 200. For example, the second low-reflection optical layer 300 can include an anisotropic birefringent material to have a phase retardation characteristic. The second low-reflection optical layer 300 can include a reactive mesogen as the anisotropic birefringent material. The second low-reflection optical layer 300 can be configured to have a transmission axis of 45° or 135° (or –45°), and can be a QWP (Quarter-Wave Plate) having a phase retardation value of λ/4.

According to one embodiment of the present disclosure, the first low-reflection optical layer 200 can be disposed on an upper surface of each of the color filters CF1, CF2, CF3 and CF4 in the emission areas EA1, EA2, EA3 and EA4 of each of the plurality of subpixels SP1, SP2, SP3 and SP4, can absorb a portion of external light incident through the substrate 111 by the light absorption pattern 210, can absorb or reflect a TE mode light component of the external light by the TE mode reflection pattern 220, and can transmit only a TM mode light component of the external light. In addition, the second low-reflection optical layer 300 can prevent the external light from being reflected by converting light polarized as the TM mode light that has passed through the TE mode reflection pattern 220 into circularly polarized light.

For example, when external light having TE and TM mode components in an unpolarized state is incident on the first low-reflection optical layer 200, a portion of the light can be absorbed by the light absorption pattern 210, and the TE mode light can be absorbed or reflected by the TE mode reflection pattern 220, thereby eliminating a portion of the external light. The second low-reflection optical layer 300 can convert the TM mode component of the external light into circularly polarized light. Then, the circularly polarized external light can be reflected by the common electrode CE and can be converted into 0° linearly polarized light while passing through the second low-reflection optical layer 300 again. The 0° linearly polarized external light can be absorbed or reflected by the TE mode reflection pattern 220, and can be mostly absorbed while passing through the light absorption pattern 210 again. Accordingly, the low-reflection optical portion 200 and 300 according to one embodiment of the present disclosure can reduce external light reflection in the plurality of subpixels SP1, SP2, SP3 and SP4.

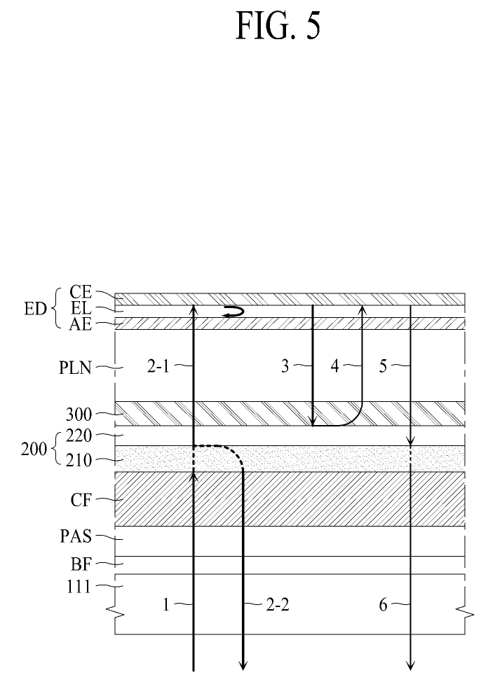

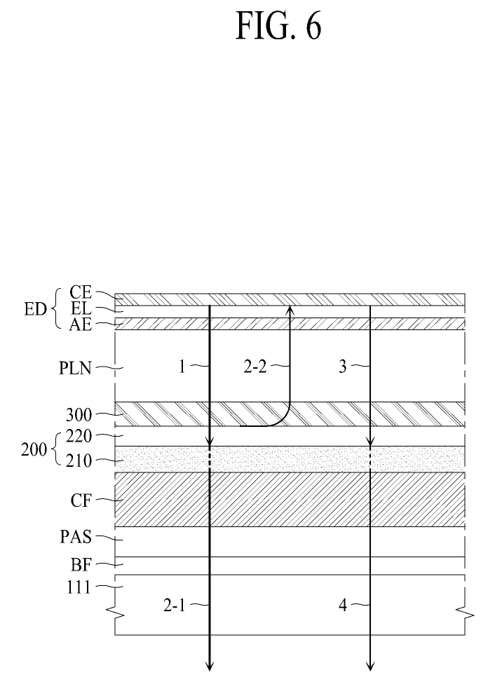

FIG. 5 illustrates a change in a path of external light in a display panel according to one embodiment of the present disclosure. FIG. 6 illustrates a change in a path of emitted light in a display panel according to one embodiment of the present disclosure.

Referring to FIGS. 5 and 6, the display panel 110 according to one embodiment of the present disclosure can reduce a reflectance of external light and can improve light extraction efficiency of emitted light.

Referring to FIG. 5, external light can be incident on the display panel 110 from the outside through the substrate 111, and the external light 1 at this time can be considered as 100% external light. The external light 1 can pass through the light absorption pattern 210, and a portion of the external light 1 can be absorbed. Since the light absorption pattern 210 is not formed over an entire incident surface but is formed in a patterned manner, it can affect only a portion of the entire external light 1. For example, the light absorption pattern 210 can absorb 50% of the external light 1. The external light 1 that has passed through the light absorption pattern 210 can be incident on the TE mode reflection pattern 220 and can be divided into external light 2-1 of a TM mode component and external light 2-2 of a TE mode component.

For example, the transmitted external light 2-1 can be 25% of the external light 1, and the reflected external light 2-2 can be 25% of the external light 1. At this time, the 25% of the transmitted external light 2-1 can be further reduced according to a TM transmittance characteristic of the TE mode reflection pattern 220, and the 25% of the reflected external light 2-2 can be further reduced according to a TE reflectance characteristic. For example, when the TM transmittance of the TE mode reflection pattern 220 is 91% and the TE reflectance is 71%, the transmitted external light 2-1 can become 23%, and the reflected external light 2-2 can become 18%.

When the transmitted external light 2-1 reaches the common electrode CE, the transmitted external light 2-1 can be reflected by the common electrode CE, and its phase can be changed to become right-handed circularly polarized light. The reflected 23% of the external light 3 can be incident on the TE mode reflection pattern 220 again, and 16% of external light 4 of a TE mode component can be re-reflected to the common electrode CE, and 16% of external light 5 can pass through the light absorption pattern 210 and can be emitted to the substrate 111 as 16% of reflected light 6. Accordingly, the incident external light 1 can output 34% of reflected light to the outside, which is composed of 18% of external light 2-2 pre-reflected by the TE mode reflection pattern 220 and 16% of external light 6 reflected through an inside of the display panel 110.

Accordingly, the display panel 110 according to one embodiment of the present disclosure can reduce a reflectance by approximately 4% compared to 38% of external light reflection in a case where a transmittance control film having a transmittance of 62% is applied.

Referring to FIG. 6, light can be emitted from the light emitting element ED of the display panel 110, and the emitted light 1 at this time can be considered as 100% emitted light. The emitted light 1 can be incident on the TE mode reflection pattern 220 and can be divided into emitted light 2-1 of a TM mode component and emitted light 2-2 of a TE mode component. For example, the transmitted emitted light 2-1 can be 50% of the emitted light 1, and the reflected emitted light 2-2 can be 50% of the emitted light 1. At this time, the 50% of the transmitted emitted light 2-1 and the 50% of the reflected emitted light 2-2 can be reduced according to a TM transmittance characteristic and a TE reflectance characteristic of the TE mode reflection pattern 220. For example, when the TM transmittance of the TE mode reflection pattern 220 is 91% and the TE reflectance is 71%, the transmitted emitted light 2-1 can become 46%, and the reflected emitted light 2-2 can become 36%.

The reflected emitted light 2-2 can reach the common electrode CE and can be reflected, and the reflected 36% of emitted light 3 can pass through the TE mode reflection pattern 220 again, and 32% of emitted light 4 can be emitted to the substrate 111 according to a TM transmittance. Accordingly, the emitted light 1 can output 78% of emitted light to the outside, which is composed of 46% of emitted light 2-1 pre-transmitted by the TE mode reflection pattern 220 and 32% of emitted light 4 reflected through an inside of the display panel 110.

Accordingly, the display panel 110 according to one embodiment of the present disclosure can improve light extraction efficiency by approximately 16% compared to 62% of emitted light output in a case where a transmittance control film is applied.

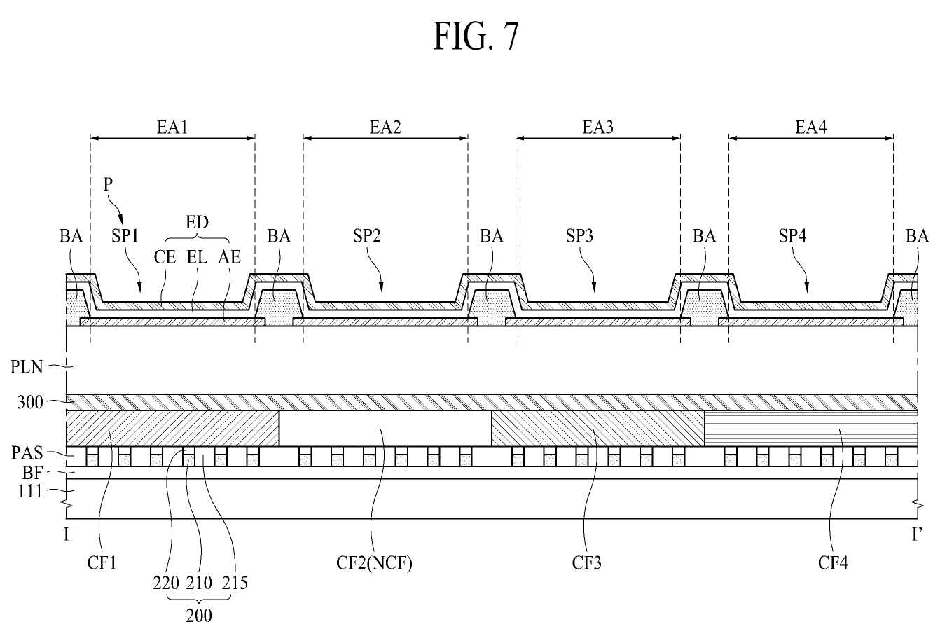

FIG. 7 is a cross-sectional view taken along line I-I′ of FIG. 3 according to another embodiment of the present disclosure. For example, FIG. 7 illustrates an embodiment in which an arrangement of a low-reflection optical portion is modified in the light emitting display apparatus described with reference to FIGS. 1 to 6. In the following description referring to FIG. 7, the same reference numerals will be used for the same components, except for the modified configurations, and their redundant descriptions will be omitted or briefly described.

Referring to FIG. 7, the low-reflection optical portion 200 and 300 according to another embodiment of the present disclosure can be disposed between the color filters CF1, CF2, CF3 and CF4 and the substrate 111. For example, the first low-reflection optical layer 200 of the low-reflection optical portion 200 and 300 can be disposed between the color filters CF1, CF2, CF3 and CF4 and the substrate 111, and the second low-reflection optical layer 300 can be disposed on the color filters CF1, CF2, CF3 and CF4.

The first low-reflection optical layer 200 can include a light absorption pattern 210 and a TE mode reflection pattern 220. The first low-reflection optical layer 200 can be formed in the passivation layer PAS. For example, the passivation layer PAS can be configured to support the light absorption pattern 210 and the TE mode reflection pattern 220. The passivation layer PAS can be composed of a non-conductive material. For example, the passivation layer PAS can be composed of an inorganic film having non-conductivity. The passivation layer PAS can be configured to surround a periphery of the light absorption pattern 210 and the TE mode reflection pattern 220. According to another embodiment of the present disclosure, the light absorption pattern 210 and the TE mode reflection pattern 220 of the first low-reflection optical layer 200 can be disposed on the passivation layer PAS and can be configured to be covered by the color filters CF1, CF2, CF3 and CF4, but the embodiments of the present disclosure are not limited thereto.

The low-reflection optical portion 200 and 300 according to another embodiment of the present disclosure may not be configured as a separate layer of the display panel 110, but can be internalized in the passivation layer PAS or the color filters CF1, CF2, CF3 and CF4. Accordingly, the light emitting display apparatus according to another embodiment of the present disclosure can reduce cost through uni-materialization, optimize a manufacturing process, reduce reflectance, and improve light efficiency.

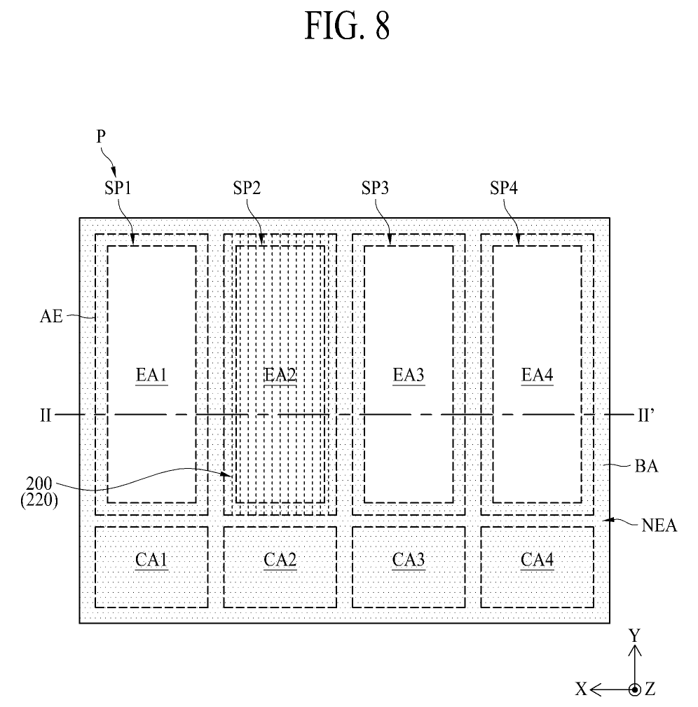

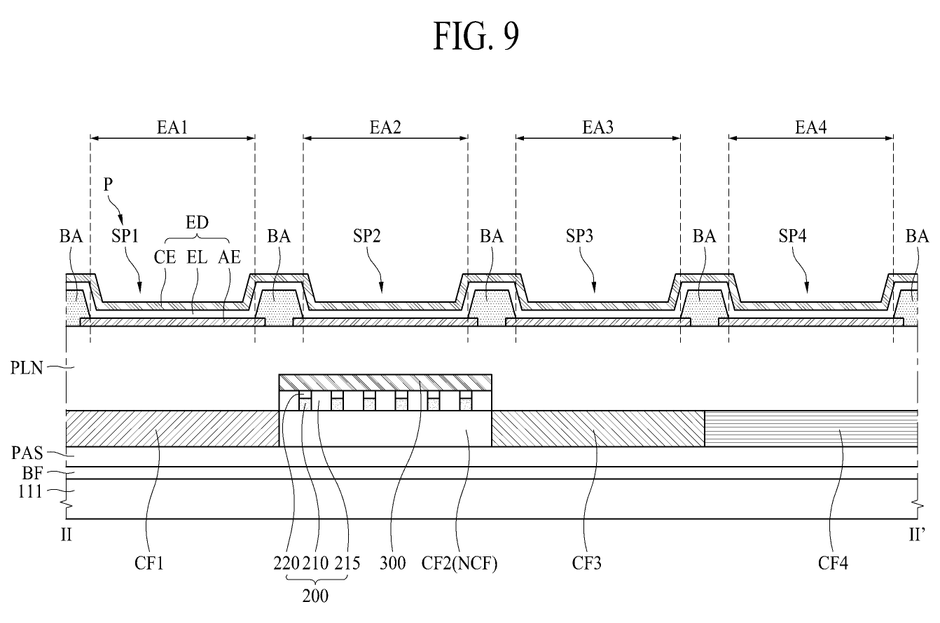

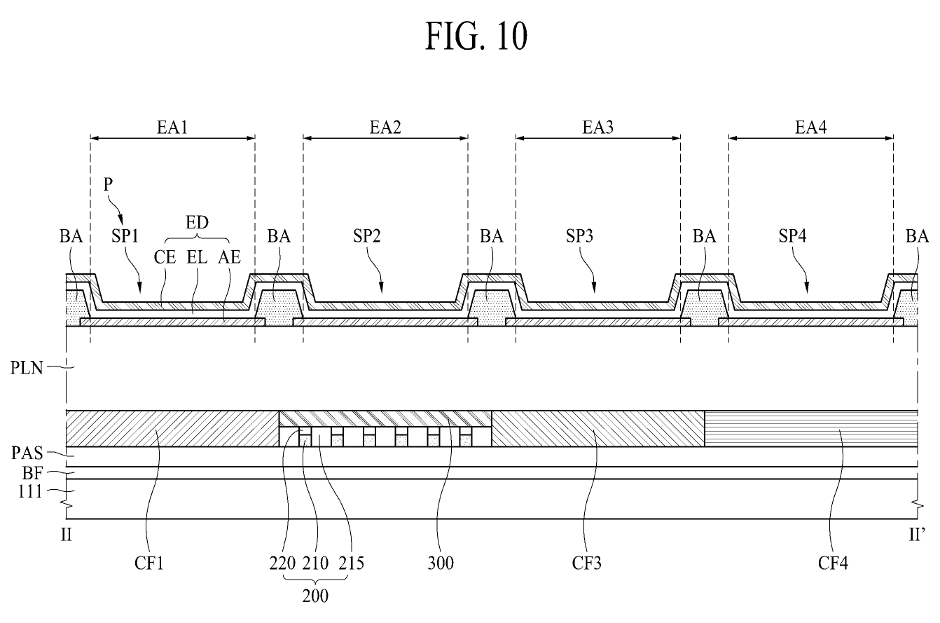

FIG. 8 illustrates a plurality of subpixels in a display panel according to another embodiment of the present disclosure. FIG. 9 is a cross-sectional view taken along line II-II′ of FIG. 8 according to another embodiment of the present disclosure. FIG. 10 is a cross-sectional view taken along line II-II′ of FIG. 8 according to another embodiment of the present disclosure. For example, FIGS. 8 to 10 illustrate embodiments in which an arrangement of a low-reflection optical portion is modified in the light emitting display apparatus described with reference to FIGS. 1 to 7. In the following description referring to FIGS. 8 to 10, the same reference numerals will be used for the same components, except for the modified configurations, and redundant descriptions will be omitted or briefly described.

Referring to FIGS. 8-10, the low-reflection optical portion 200 and 300 according to another embodiment of the present disclosure can be disposed in at least one of the plurality of subpixels SP1, SP2, SP3 and SP4. For example, the low-reflection optical portion 200 and 300 can be disposed in the second subpixel SP2 among the plurality of subpixels SP1, SP2, SP3 and SP4.

Referring to FIG. 9, the low-reflection optical portion 200 and 300 according to another embodiment of the present disclosure can be disposed on the second color filter CF2 of the second subpixel SP2. For example, the second subpixel SP2 can be a white subpixel that emits white light of the light emitting element ED as it is.

By selectively disposing the low-reflection optical portion 200 and 300 in the second subpixel SP2, a cell reflectance of the second subpixel SP2 having a relatively high reflectance compared to other subpixels SP1, SP3 and SP4 can be selectively reduced.

In addition, the low-reflection optical portion 200 and 300 can be disposed in one or more selected subpixels among the plurality of subpixels SP1, SP2, SP3 and SP4. For example, the low-reflection optical portion 200 and 300 can be selectively disposed in the second subpixel SP2, which is a white subpixel, and the fourth subpixel SP4, which is a green subpixel, or can be disposed in all of the first to fourth subpixels SP1, SP2, SP3 and SP4, but the embodiments of the present disclosure are not limited thereto.

Referring to FIG. 10, the second subpixel SP2 according to another embodiment of the present disclosure can be a white subpixel in which the color filter may not be disposed.

The low-reflection optical portion 200 and 300 can be selectively disposed in the second subpixel SP2 in which the color filter is not disposed. The low-reflection optical portion 200 and 300 can be disposed on the passivation layer PAS corresponding to the second subpixel SP2.

The low-reflection optical portion 200 and 300 can be disposed between the first subpixel SP1 adjacent to the second subpixel SP2 and the second subpixel SP2 on the passivation layer PAS. For example, the low-reflection optical portion 200 and 300 can have the same or a different height as the color filters CF1 and CF3 of the adjacent first and second subpixels SP1 and SP2. For example, the low-reflection optical portion 200 and 300 can be configured to have the same height as the first and third color filters CF1 and CF2 within a range of process variation.

According to another embodiment of the present disclosure, the low-reflection optical portion 200 and 300 can be selectively disposed in the second subpixel SP2 in which the color filter is not disposed, thereby selectively reducing a cell reflectance of the second subpixel SP2 having a relatively high reflectance compared to other subpixels SP1, SP3 and SP4 due to the absence of the color filter. Accordingly, the light emitting display apparatus according to another embodiment of the present disclosure can optimize a cell reflectance of each of the subpixels SP1, SP2, SP3 and SP4, can reduce reflection by external light, and can improve light extraction efficiency.

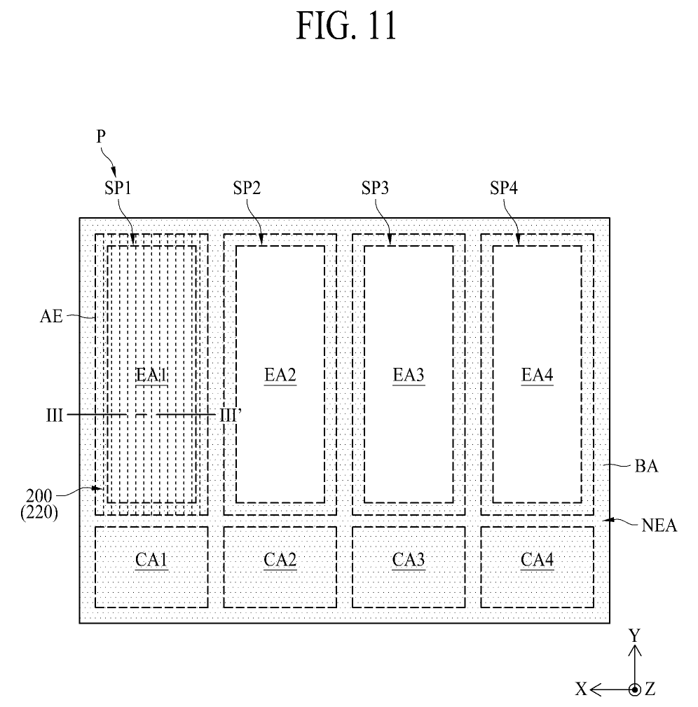

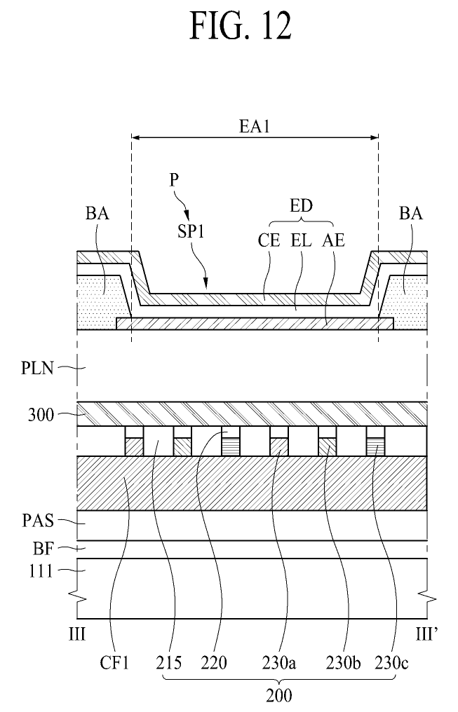

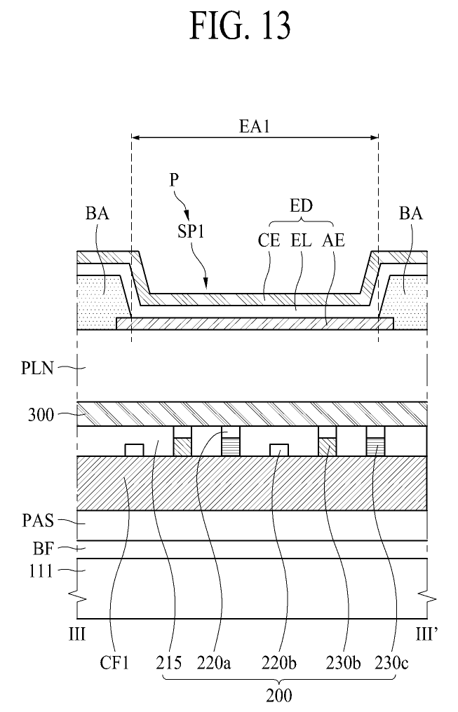

FIG. 11 illustrates a plurality of subpixels in a display panel according to another embodiment of the present disclosure. FIG. 12 is a cross-sectional view taken along line III-III′ of FIG. 11 according to another embodiment of the present disclosure. FIG. 13 is a cross-sectional view taken along line III-III′ of FIG. 11 according to another embodiment of the present disclosure. For example, FIGS. 11-13 illustrate embodiments in which a configuration of a low-reflection optical portion is modified in the light emitting display apparatus described with reference to FIGS. 1-10. In the following description referring to FIGS. 11-13, the same reference numerals will be used for the same components, except for the modified configurations, and redundant descriptions will be omitted or briefly described.

Referring to FIGS. 11-13, the low-reflection optical portion 200 and 300 according to another embodiment of the present disclosure can be disposed in at least one of the plurality of subpixels SP1, SP2, SP3 and SP4. For example, the low-reflection optical portion 200 and 300 can be disposed in the first subpixel SP1 among the plurality of subpixels SP1, SP2, SP3 and SP4. For example, the first subpixel SP1 can be disposed with a first color filter CF1 that converts white light into red light.

By selectively disposing the low-reflection optical portion 200 and 300 in the first subpixel SP1, a reflected color and a visual perception of the first subpixel SP1 can be improved. In addition, the low-reflection optical portion 200 and 300 can be disposed in one or more selected subpixels among the plurality of subpixels SP1, SP2, SP3 and SP4. For example, the low-reflection optical portion 200 and 300 can be selectively disposed in one or more subpixels that require improvement in reflected color and visual perception among the plurality of subpixels SP1, SP2, SP3 and SP4, or can be disposed in all of the first to fourth subpixels SP1, SP2, SP3 and SP4, but the embodiments of the present disclosure are not limited thereto.

Referring to FIGS. 12 and 13, the low-reflection optical portion 200 and 300 according to another embodiment of the present disclosure can include a first low-reflection optical layer 200 and a second low-reflection optical layer 300. For example, the low-reflection optical portion 200 and 300 can include a light absorption pattern 210, a TE mode reflection pattern 220, and a protective layer 215.

Referring to FIG. 12, the first low-reflection optical layer 200 according to another embodiment of the present disclosure can include one or more light absorption patterns 230a, 230b and 230c formed of the same color material as the color filters CF1, CF2, CF3 and CF4 corresponding to each of the subpixels SP1, SP2, SP3 and SP4. For example, the light absorption patterns 230a, 230b and 230c can include a first light absorption pattern 230a formed of the same material as the first color filter CF1, a second light absorption pattern 230b formed of the same material as the third color filter CF3, and a third light absorption pattern 230c formed of the same material as the fourth color filter CF4.

The first low-reflection optical layer 200 can include a light absorption pattern 230a, 230b and 230c composed of all of the color filters CF1, CF3 and CF4 that represent colors, including a first light absorption pattern 230a formed of the same material as the first color filter CF1 on which the first low-reflection optical layer 200 is disposed.

Referring to FIG. 13, the first low-reflection optical layer 200 according to another embodiment of the present disclosure can include light absorption patterns 230b and 230c composed of the remaining color filters CF3 and CF4 except for the first color filter CF1 on which the first low-reflection optical layer 200 is disposed. In addition, the first low-reflection optical layer 200 can include a first TE reflection pattern 220a stacked on the light absorption patterns 230b and 230c and a second TE reflection pattern 220b directly disposed on the first color filter CF1.

For example, the second TE reflection pattern 220b can add a red reflected color by reflecting external light that has passed through the first color filter CF1 on which the first low-reflection optical layer 200 is disposed. In addition, the second TE reflection pattern 220b can overlap the first color filter CF1 and can add a neutral reflected color in which red and blue or red and green are overlapped by reflecting external light incident through the light absorption patterns 230b and 230c that transmit a color different from the first color filter CF1.

According to another embodiment of the present disclosure, the first low-reflection optical layer 200 can improve a reflected color and a visual perception for external light by including light absorption patterns 230a, 230b and 230c composed of at least one color filter among the plurality of color filters CF1, CF3 and CF4. Accordingly, the light emitting display apparatus according to another embodiment of the present disclosure can optimize a cell reflectance of each of the subpixels SP1, SP2, SP3 and SP4, can reduce reflection by external light, can improve light extraction efficiency, and can improve a reflected color and a visual perception.

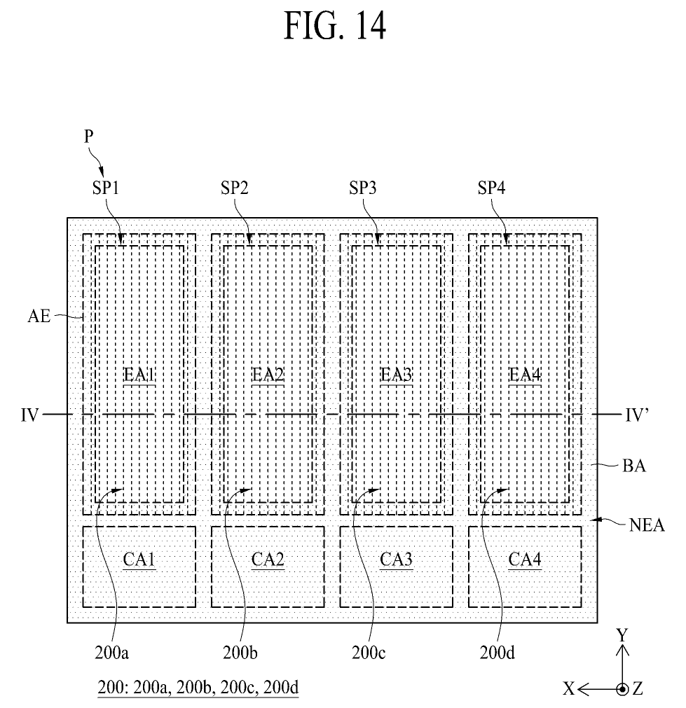

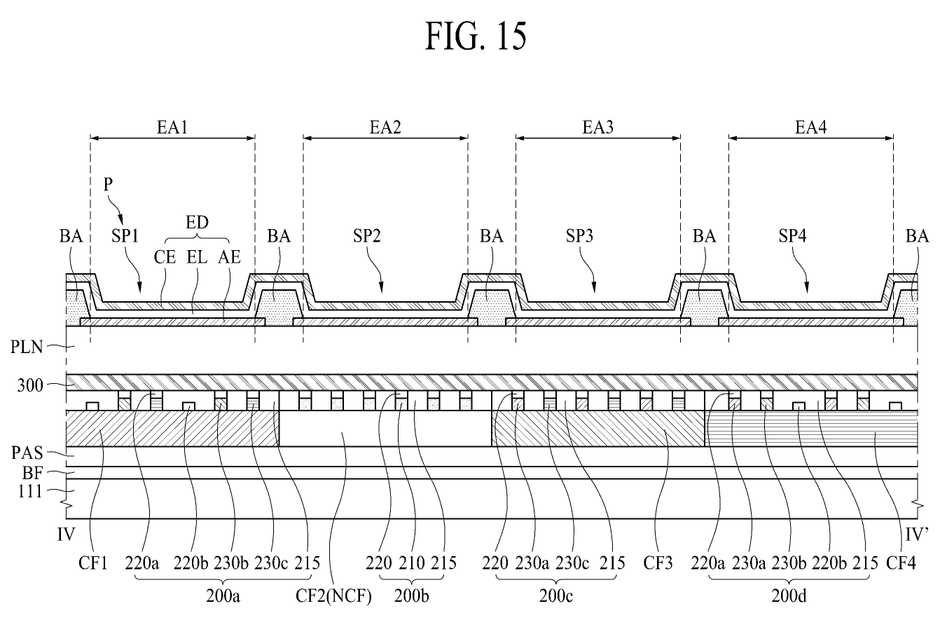

FIG. 14 illustrates a plurality of subpixels in a display panel according to another embodiment of the present disclosure. FIG. 15 is a cross-sectional view taken along line IV-IV′ of FIG. 14 according to another embodiment of the present disclosure. For example, FIGS. 14 and 15 illustrate embodiments in which a configuration and an arrangement of a low-reflection optical portion are modified in the light emitting display apparatus described with reference to FIGS. 1-13. In the following description referring to FIGS. 14 and 15, the same reference numerals will be used for the same components, except for the modified configurations, and redundant descriptions will be omitted or briefly described.

Referring to FIGS. 14 and 15, the first low-reflection optical layer 200 according to another embodiment of the present disclosure can include a first-1 low-reflection optical layer 200a, a first-2 low-reflection optical layer 200b, a first-3 low-reflection optical layer 200c, and a first-4 low-reflection optical layer 200d, which are composed of different materials for each of the subpixels SP1, SP2, SP3 and SP4, respectively.

Referring to FIG. 15, the first-1 low-reflection optical layer 200a, the first-2 low-reflection optical layer 200b, the first-3 low-reflection optical layer 200c, and the first-4 low-reflection optical layer 200d according to another embodiment of the present disclosure can be disposed in the respective subpixels SP1, SP2, SP3 and SP4.

The first-1 low-reflection optical layer 200a can be disposed in the first subpixel SP1 and can include a second light absorption pattern 230b and a third light absorption pattern 230c composed of the other color filters CF3 and CF4 except for the first color filter CF1. In addition, the first-1 low-reflection optical layer 200a can include a first TE reflection pattern 220a and a second TE reflection pattern 220b.

The first-2 low-reflection optical layer 200b can be disposed on the second subpixel SP2 and can include a light absorption pattern 210 and a TE mode reflection pattern 220.

The first-3 low-reflection optical layer 200c can be disposed on the third subpixel SP3 and can include a first light absorption pattern 230a and a third light absorption pattern 230c, which are formed of color filters CF1 and CF4 other than the third color filter CF3.

The first-4 low-reflection optical layer 200d can be disposed on the fourth subpixel SP4 and can include a first light absorption pattern 230a and a second light absorption pattern 230b, which are formed of color filters CF1 and CF3 other than the fourth color filter CF4. In addition, the first-4 low-reflection optical layer 200d can include a first TE reflection pattern 220a and a second TE reflection pattern 220b.

According to another embodiment of the present disclosure, by disposing the plurality of first low-reflection optical layers 200a, 200b, 200c and 200d, which are formed of different materials from each other, on each of the plurality of subpixels SP1, SP2, SP3 and SP4, reflection color and visibility with respect to external light can be optimally improved for each of the subpixels SP1, SP2, SP3 and SP4. Accordingly, a light emitting display apparatus according to another embodiment of the present disclosure can optimize cell reflectance of each of the subpixels SP1, SP2, SP3 and SP4, can reduce reflection caused by external light while improving light extraction efficiency, and can optimally improve reflection color and visibility.

A light emitting display apparatus/device according to one or more embodiments of the present disclosure will be described below.

A light emitting display apparatus according to one or more embodiments of the present disclosure can include a substrate including a plurality of subpixels having an emission area and a non-emission area, a pixel circuit disposed in the non-emission area on the substrate, at least one insulating layer disposed on the pixel circuit, and a color filter disposed on the at least one insulating layer, the color filter corresponding to at least one of the plurality of subpixels, one or more of the plurality of subpixels can include a low-reflection optical portion having at least one transverse electric (TE) mode reflection pattern adjacent to or in contact with the color filter in the emission area.

According to one or more embodiments of the present disclosure, the at least one TE mode reflection pattern can include a plurality of TE mode reflection patterns, and the plurality of TE mode reflection patterns can extend in a first direction of the emission area or in a second direction intersecting the first direction, and can be arranged to be spaced apart from each other.

According to one or more embodiments of the present disclosure, the plurality of TE mode reflection patterns can be configured to have a width of each TE mode reflection pattern or a distance between adjacent TE mode reflection patterns smaller than a wavelength range of light of a corresponding subpixel.

According to one or more embodiments of the present disclosure, the width of each TE mode reflection pattern or the distance between adjacent TE mode reflection patterns can be 200 nm to 1000 nm.

According to one or more embodiments of the present disclosure, the TE mode reflection pattern can include a conductive material or a conductive organic material.

According to one or more embodiments of the present disclosure, the low-reflection optical portion can be disposed on the color filter.

According to one or more embodiments of the present disclosure, the low-reflection optical portion can be disposed between the color filter and the substrate.

According to one or more embodiments of the present disclosure, the low-reflection optical portion can include a portion of the at least one insulating layer.

According to one or more embodiments of the present disclosure, the low-reflection optical portion can include a first low-reflection optical layer disposed between the color filter and the substrate, and a second low-reflection optical layer disposed on the color filter, the first low-reflection optical layer can include a portion of the at least one insulating layer.

According to one or more embodiments of the present disclosure, the low-reflection optical portion can be disposed in each of the plurality of subpixels.

According to one or more embodiments of the present disclosure, the low-reflection optical portion can be configured to include different materials in each of the plurality of subpixels.

According to one or more embodiments of the present disclosure, at least one of the plurality of subpixels can be a white subpixel in which the color filter is not disposed, and the low-reflection optical portion can be disposed on the at least one insulating layer corresponding to the white subpixel, and can have the same or a different height as the color filter between the white subpixel and other subpixels adjacent to the white subpixel.

According to one or more embodiments of the present disclosure, the low-reflection optical portion can include a first low-reflection optical layer in which a plurality of TE mode reflection patterns are arranged in a first direction or in a second direction intersecting the first direction, and which includes a protective layer supporting the plurality of TE mode reflection patterns, and a second low-reflection optical layer disposed on the first low-reflection optical layer and having a phase retardation characteristic.

According to one or more embodiments of the present disclosure, a phase retardation value of the second low-reflection optical layer can be λ/4.

According to one or more embodiments of the present disclosure, the first low-reflection optical layer can further include a light absorption pattern corresponding to each of the plurality of TE mode reflection patterns and having a light absorption characteristic, and the light absorption pattern can be disposed below the TE mode reflection pattern.

According to one or more embodiments of the present disclosure, the light absorption pattern can include a light absorbing material or a black material.

According to one or more embodiments of the present disclosure, the first low-reflection optical layer can include a portion in which the TE mode reflection pattern is disposed and a portion in which the light absorption pattern and the TE mode reflection pattern are stacked.

According to one or more embodiments of the present disclosure, the light absorption pattern can include a same color filter material as a color filter corresponding to each of the plurality of subpixels.

According to one or more embodiments of the present disclosure, the plurality of subpixels can include a white subpixel in which the color filter is not disposed, a red subpixel that emits red light, a blue subpixel that emits blue light, and a green subpixel that emits green light, and the first low-reflection optical layer can include at least one of: a portion in which the TE mode reflection pattern is disposed; a portion in which the TE mode reflection pattern and a light absorption pattern comprising a color filter of the red subpixel are stacked; a portion in which the TE mode reflection pattern and a light absorption pattern comprising a color filter of the blue subpixel are stacked; and a portion in which the TE mode reflection pattern and a light absorption pattern comprising a color filter of the green subpixel are stacked.

According to one or more embodiments of the present disclosure, the first low-reflection optical layer corresponding to each of the red subpixel, the blue subpixel, and the green subpixel can include either a light absorption pattern comprising at least one color filter, a light absorption pattern comprising remaining color filters except for a color filter corresponding to the respective subpixel, or a light absorption pattern comprising all color filters.

The above-described feature, structure, and effect of the present disclosure are included in at least one embodiment of the present disclosure, but are not limited to only one embodiment. Furthermore, the feature, structure, and effect described in at least one embodiment of the present disclosure can be implemented through combination or modification of other embodiments by those skilled in the art. Therefore, content associated with the combination and modification should be construed as being within the scope of the present disclosure.

It will be apparent to those skilled in the art that various modifications and variations can be made in the present disclosure without departing from the spirit or scope of the disclosures. Thus, it is intended that the present disclosure covers the modifications and variations of this disclosure provided they come within the scope of the appended claims and their equivalents.

What is claimed is:

1. A light emitting display apparatus comprising:
a substrate including a plurality of subpixels having an emission area and a non-emission area;
a pixel circuit disposed in the non-emission area on the substrate;
at least one insulating layer disposed on the pixel circuit; and
a color filter disposed on the at least one insulating layer, the color filter corresponding to at least one of the plurality of subpixels,
wherein one or more of the plurality of subpixels includes a low-reflection optical portion having at least one transverse electric (TE) mode reflection pattern adjacent to or in contact with the color filter in the emission area.

2. The light emitting display apparatus of claim 1, wherein the at least one TE mode reflection pattern includes a plurality of TE mode reflection patterns, and
wherein the plurality of TE mode reflection patterns extend in a first direction of the emission area or in a second direction intersecting the first direction, and are arranged to be spaced apart from each other.

3. The light emitting display apparatus of claim 2, wherein a width of each of the plurality of TE mode reflection patterns or a distance between adjacent TE mode reflection patterns among the plurality of TE mode reflection patterns is smaller than a wavelength range of light of a corresponding subpixel.

4. The light emitting display apparatus of claim 3, wherein the width of each of the plurality of TE mode reflection patterns or the distance between the adjacent TE mode reflection patterns is 200 nm to 1000 nm.

5. The light emitting display apparatus of claim 1, wherein each of the plurality of TE mode reflection patterns includes a conductive material or a conductive organic material.

6. The light emitting display apparatus of claim 1, wherein the low-reflection optical portion is disposed on the color filter.

7. The light emitting display apparatus of claim 1, wherein the low-reflection optical portion is disposed between the color filter and the substrate.

8. The light emitting display apparatus of claim 7, wherein the low-reflection optical portion includes a portion of the at least one insulating layer.

9. The light emitting display apparatus of claim 1, wherein the low-reflection optical portion comprises:
a first low-reflection optical layer disposed between the color filter and the substrate; and
a second low-reflection optical layer disposed on the color filter,
wherein the first low-reflection optical layer includes a portion of the at least one insulating layer.

10. The light emitting display apparatus of claim 1, wherein the low-reflection optical portion is disposed in each of the plurality of subpixels.

11. The light emitting display apparatus of claim 10, wherein the low-reflection optical portion is configured to include different materials in each of the plurality of subpixels.

12. The light emitting display apparatus of claim 1, wherein at least one of the plurality of subpixels is a white subpixel in which the color filter is not disposed, and
wherein the low-reflection optical portion is disposed on the at least one insulating layer corresponding to the white subpixel, and has a same or different height as the color filter between the white subpixel and other subpixels adjacent to the white subpixel.

13. The light emitting display apparatus of claim 1, wherein the at least one TE mode reflection pattern includes a plurality of TE mode reflection patterns, and
wherein the low-reflection optical portion comprises:
a first low-reflection optical layer in which the plurality of TE mode reflection patterns are arranged in a first direction or in a second direction intersecting the first direction, the first low-reflection optical layer including a protective layer supporting the plurality of TE mode reflection patterns; and
a second low-reflection optical layer disposed on the first low-reflection optical layer and having a phase retardation characteristic.

14. The light emitting display apparatus of claim 13, wherein a phase retardation value of the second low-reflection optical layer is λ/4.

15. The light emitting display apparatus of claim 13, wherein the first low-reflection optical layer further includes a light absorption pattern corresponding to a TE mode reflection pattern among the plurality of TE mode reflection patterns and having a light absorption characteristic, and
wherein the light absorption pattern is disposed below the corresponding TE mode reflection pattern.

16. The light emitting display apparatus of claim 15, wherein the light absorption pattern includes a light absorbing material or a black material.

17. The light emitting display apparatus of claim 15, wherein the first low-reflection optical layer includes a portion in which the corresponding TE mode reflection pattern is disposed and a portion in which the light absorption pattern and the corresponding TE mode reflection pattern are stacked.

18. The light emitting display apparatus of claim 15, wherein the light absorption pattern includes a same color filter material as a color filter corresponding to one of the plurality of subpixels.

19. The light emitting display apparatus of claim 18, wherein the plurality of subpixels include a white subpixel in which the color filter is not disposed, a red subpixel configured to emit red light, a blue subpixel configured to emit blue light, and a green subpixel configured to emit green light, and
wherein the first low-reflection optical layer includes at least one of:
a portion in which the corresponding TE mode reflection pattern is disposed;
a portion in which the corresponding TE mode reflection pattern and a light absorption pattern comprising a color filter of the red subpixel are stacked;
a portion in which the corresponding TE mode reflection pattern and a light absorption pattern comprising a color filter of the blue subpixel are stacked; and
a portion in which the corresponding TE mode reflection pattern and a light absorption pattern comprising a color filter of the green subpixel are stacked.

20. The light emitting display apparatus of claim 19, wherein the first low-reflection optical layer corresponding to each of the red subpixel, the blue subpixel, and the green subpixel includes:
a light absorption pattern comprising at least one color filter,
a light absorption pattern comprising remaining color filters except for a color filter corresponding to the respective subpixel; or
a light absorption pattern comprising all color filters.
